(19) United States
(12) Patent Application Publication
(10) Pub. No.: US 2023/0116731 A1
(43) Pub. Date: Apr. 13, 2023

(54) INTELLIGENT TIME-STEPPING FOR NUMERICAL SIMULATIONS

(71) Applicant: Schlumberger Technology Corporation, Sugar Land, TX (US)

(72) Inventors: Soham SHETH, Oxford (GB); Kieran NEYLON, Shepperton (GB); Ghazala FAZIL, Calgary (CA); Francois MCKEE, Didcot (GB); Jonathan NORRIS, Steventon (GB)

(21) Appl. No.: 18/052,266

(22) Filed: Nov. 3, 2022

Related U.S. Application Data
(63) Continuation of application No. PCT/US2021/030705, filed on May 4, 2021.
(60) Provisional application No. 63/020,824, filed on May 6, 2020.

(51) Int. Cl. G01V 99/00; G06F 30/27

(52) U.S. Cl. CPC G01V 99/005; G06F 30/27

(57) ABSTRACT

Systems and methods are provided for modeling a reservoir. An exemplary method includes: receiving a reservoir model associated with a reservoir workflow process; modifying the reservoir model associated with the reservoir workflow process using an optimum time-step strategy; extracting features from the reservoir model along with first time-step sizes; generating a first set of data for devising a training set using the first time-step sizes; determining whether the selected amount of the first set of data reaches a predetermined level; triggering a real-time training using the training set and a machine learning (ML) algorithm; generating an ML model having second time-step sizes using the training set; selecting the first step-sizes or the second step-sizes based on the confidence level; sending the selected step-sizes to a simulator for processing; receiving results from the simulator that used the selected step-sizes; and determining whether results from the simulator require updating the training set.

### CROSS REFERENCE TO RELATED APPLICATIONS

This application is a continuation of PCT Patent App. No. PCT/US2021/030705, which was filed on May 4, 2021, which in turn claims priority to U.S. provisional application No. 63/020,824 filed on May 6, 2020. The contents of the foregoing applications are incorporated herein in its entirety.

### BACKGROUND

Accurate and reliable time integration is needed for numerical simulation of dynamic systems, such as in hydrocarbon reservoirs. Time-step size is greatly influenced by the discretization that is employed for a given model. Explicit discretization is only stable for small time steps, restricted by the Courant-Friedrichs-Lewy (CFL) condition. For implicit time integration, the theoretical time step size has no stability restriction. Convergence, on the other hand, is not guaranteed for any system where the nonlinear solution state is outside the contraction region. There are many heuristic techniques of selecting time-step size used in various simulation models.

The algorithms in a simulator have no inherent CFL type stability limit and hence the choice of time-step selection has been mostly limited by a heuristic set of parameters. Time truncation errors have been successfully used to maintain accuracy; however, for many complex models, it is too restrictive.

In such cases, the main driver for time-step choice is the nonlinear convergence. In essence, if the number of Newton iterations are small, the time-step size can be increased by a factor whereas if the iterations exceed a predetermined limit, the simulation is stopped, and repeated from the previous state with a small time-step (which results in a significant waste of computational effort). Recently, a heuristic based on fuzzy logic has been proposed which has produced encouraging results but remains in the pool of heuristic methods which do not guarantee optimal results.

Researchers have proposed a time-step selector based on a PID controller. The PID controller is governed by the user prescribed limit on the changes in pressure and saturation and adapts time-steps based on this logic. The PID controller also shows some improvements in the computational efficiency of the scheme, but the tuning of the PID controller is one of the most important stages of implementation of the controller. Additionally, the controller works on user input which in many cases might not be optimal and could result in inefficiencies. Some seminal works are based on explicit stability requirements and local truncation error estimates, which form the cornerstone of many research projects and ideas behind state-of-the-art time-stepping methods in reservoir simulation.

A new approach for accurate and reliable time integration for numerical simulation of dynamic systems is provided herein.

### BRIEF DESCRIPTION OF THE DRAWINGS

For a better understanding of the aforementioned embodiments as well as additional embodiments thereof, reference should be made to the Detailed Description below, in conjunction with the following drawings in which like reference numerals refer to corresponding parts throughout the figures.

FIG. 1A illustrates a simplified schematic view of a survey operation performed by a survey tool at an oil field, in accordance with some embodiments.

FIG. 1B illustrates a simplified schematic view of a drilling operation performed by drilling tools, in accordance with some embodiments.

FIG. 1C illustrates a simplified schematic view of a production operation performed by a production tool, in accordance with some embodiments.

FIG. 2 illustrates a schematic view, partially in cross section, of an oilfield, in accordance with some embodiments.

FIG. 3 illustrates a static workflow which includes a machine learning model as an inference engine, in accordance with some embodiments.

FIG. 4 shows a second workflow for a real-time train-infer-reinforce type model, in accordance with some embodiments.

FIG. 5 illustrates a dynamic workflow which includes artificial intelligent time-stepping, in accordance with some embodiments.

FIG. 6 illustrates a snapshot of a tree from a random forest model for a compositional simulation model, in accordance with some embodiments.

FIG. 7 illustrates a snapshot of a tree from a random forest model for a thermal simulation model, in accordance with some embodiments.

FIG. 8 illustrates a time-step comparison for a thermal simulation model.

FIG. 9 illustrates a comparison in actual run times for the simulation model with and without machine learning (ML), in accordance with some embodiments.

FIG. 10 illustrates an example of a computing system for carrying out some of the methods of the present disclosure, in accordance with some embodiments.

### BRIEF SUMMARY

According to one aspect of the subject matter described in this disclosure, a method for modeling a reservoir is provided. The method includes the following: receiving, using one or more computing device processors, a reservoir model associated with a reservoir workflow process; modifying, using the one or more computing device processors, the reservoir model associated with the reservoir workflow process using an optimum time-step strategy; extracting, using the one or more computing device processors, features from the reservoir model along with first time-step sizes; generating, using the one or more computing device processors, a first set of data for devising a training set using the first time-step sizes; collecting, using the one or more computing device processors, a selected amount of the first set of data for the training set; determining, using the one or more computing device processors, whether the selected amount of the first set of data reaches a predetermined level; in response to the selected amount of the first set of data reaching the predetermined level, triggering a real-time training using the training set and a machine learning (ML) algorithm; generating, using the one or more computing device processors, an ML model having second time-step sizes using the training set; comparing, using the one or more computing device processors, the first time-step sizes and the second time-step sizes to generate a confidence level; selecting, using the one or more computing device processors, the first step-sizes or the second step-sizes based on the confidence level; sending, using the one or more computing device processors, the selected step-sizes to a simulator for processing; receiving, using the one or more computing device processors, results from the simulator that used the selected step-sizes; and determining, using the one or more computing device processors, whether results from the simulator require updating the training set.

According to another aspect of the subject matter described in this disclosure, a method for modeling complex processes is provided. The method includes the following: receiving, using one or more computing device processors, a model associated with a workflow process; modifying, using the one or more computing device processors, the model associated with the workflow process using an optimum time-step strategy; extracting, using the one or more computing device processors, features from the model along with first time-step sizes used for analysis; generating, using the one or more computing device processors, a first set of data for devising a training set using the first time-step sizes; collecting, using the one or more computing device processors, a selected amount of the first set of data for the training set; determining, using the one or more computing device processors, whether the selected amount of the first set of data reaches a predetermined level; in response to the selected amount of the first set of data reaching the predetermined level, triggering a real-time training of a machine learning (ML) algorithm using the training set; generating, using the one or more computing device processors, an ML model having second time-step sizes using the training set; comparing, using the one or more computing device processors, the first time-step sizes and the second time-step sizes to generate a confidence level; determining whether the confidence level is below a threshold; and in response to the confidence level being below the threshold, updating, using the one or more computing device processors, the training set.

According to another aspect of the subject matter described in this disclosure, a system for modeling a reservoir is provided. The system includes one or more computing device processors. Also, the system includes one or more computing device memories, coupled to the one or more computing device processors. The one or more computing device memories store instructions executed by the one or more computing device processors. The instructions are configured to: receive a reservoir model associated with a reservoir workflow process; modify the reservoir model associated with the reservoir workflow process using an optimum time-step strategy; extract features from the reservoir model along with first time-step sizes used for analysis; generate a first set of data for devising a training set using the first time-step sizes; collect a selected amount of the first set of data for the training set; determine whether the selected amount of the first set of data reaches a predetermined level; in response to the selected amount of the first set of data reaching the predetermined level, trigger a real-time training using the training set using a machine learning (ML) algorithm; generate an ML model having second time-step sizes using the training set; compare the first time-step sizes and the second time-step sizes to generate a confidence level; select the first step-sizes or the second step-sizes base on the confidence level; send the selected step-sizes to a simulator for processing; receive results from the simulator that used the selected step-sizes; and determine whether results from the simulator require updating the training set.

Additional features and advantages of the present disclosure are described in, and will be apparent from, the detailed description of this disclosure.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc., may be used herein to describe various elements, these elements should not be limited by these terms. These terms are used to distinguish one element from another. For example, a first object or step could be termed a second object or step, and, similarly, a second object or step could be termed a first object or step, without departing from the scope of the invention. The first object or step, and the second object or step, are both objects or steps, respectively, but they are not to be considered the same object or step.

The terminology used in the description of the invention herein is for the purpose of describing particular embodiments and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combination of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context.

Those with skill in the art will appreciate that while some terms in this disclosure may refer to absolutes, e.g., all source receiver traces, each of a plurality of objects, etc., the methods and techniques disclosed herein may also be performed on fewer than all of a given thing, e.g., performed on one or more components and/or performed on one or more source receiver traces. Accordingly, in instances in the disclosure where an absolute is used, the disclosure may also be interpreted to be referring to a subset.

The computing systems, methods, processing procedures, techniques and workflows disclosed herein are more efficient and/or effective methods for developing a Machine Learning (ML) model used to drive a simulator by selecting an r time-step strategy, which are generally a class of iteration-based approaches that heuristically create improved time-steps during a simulation process. In this disclosure, challenges in the numerical modeling of oil and gas recovery processes from subsurface reservoirs are addressed but the disclosure is generally applicable to any simulation which is governed by an advection-diffusion-reaction type process.

This approach consumes data from the physical state of the system as well as from derived mathematical parameters that describe the nonlinear partial differential equations. A machine learning method (e.g. random forest regression, neural network) interprets and classifies the input parameter data and simulator performance data and then selects an optimized time-step size. Trained models are used for inference in real-time (considered as substantially instantaneous), and hence do not introduce any extra cost during the simulation.

The considered parameters include the previous time-step size, the magnitude of solution updates and other measures of the characteristics of the solution (such as CFL number), the convergence conditions, the behavior of both non-linear and linear solvers, well events, the type of fluid, and recovery methods used. The systems and methods work as a standalone application, and the learning gained from training the time-step predictor on one simulation model can be transferred and applied to similar simulation models. Finally, the solution can be applied to a range of problems on both on-premise clusters and cloud-based simulations.

The particulars shown herein are by way of example and for purposes of illustrative discussion of the embodiments of the subject disclosure only and are presented in the cause of providing what is believed to be the most useful and readily understood description of the principles and conceptual aspects of the subject disclosure. In this regard, no attempt is made to show structural details in more detail than is necessary for the fundamental understanding of the subject disclosure, the description taken with the drawings making apparent to those skilled in the art how the several forms of the subject disclosure may be embodied in practice. Furthermore, like reference numbers and designations in the various drawings indicate like elements.

The prediction of oil and gas recovery from underground reservoirs is a complex modeling activity, and like many other situations involving dynamic (fluid/energy) volumetric flow systems (e.g. geothermal recovery, CO₂ sequestration, weather and ocean current forecasting), modeling approaches generally use numerical methods, where a solution at one point in time is projected forward over a small time-step to the next point in time and this process is repeated to calculate the solution over the whole period of interest.

Larger time-steps are advantageous because they allow simulations to progress more quickly, but if the time-step becomes too large then explicit methods (which use the current solution state to calculate fluid properties) are not stable and cannot be used. For this reason, implicit formulations (which use the unknown future solution state to estimate the fluid properties) are generally preferred as they are unconditionally stable.

However, in practice the large time-steps promised by unconditional stability are not always possible to achieve. If too large a time-step is sought, the system being solved may become too nonlinear, and its solution may require an impractically large number of iterations to converge. In such cases, the process is normally abandoned, and the solution is set back to the previous time, and a new solution attempt is made with a smaller time-step (the time-step is “chopped”). This abandonment of calculations and resetting wastes both computational resources and real time. A balance is desired—an optimally sized time-step would be one large enough to allow rapid progression through the simulation but small enough to prevent chops.

Unfortunately, this size is not easy to predict. The scenarios being modeled may differ widely in their characteristics and complexity and the time-step selection strategy needs to account for this. Moreover, conditions during the simulation may change significantly over time, meaning that the optimal time-step selection strategy may be different at different stages of the simulation run. To date, many heuristic strategies have been developed and implemented but none have been found to work universally.

One embodiment described herein may use AI and machine-learning techniques to analyze the mathematical and physical state of the underlying model as it changes during the simulation run in order to predict and apply optimally sized time-steps.

In an embodiment, a reservoir simulator time-step selection approach is described which may use machine-learning (ML) techniques to analyze the mathematical and physical state of the system and predict time-step sizes which are large while still being efficient to solve, thus making the simulation faster. An optimal time-step choice may avoid wasted non-linear and linear equation set-up work when the time-step is too small and avoids highly non-linear systems that take many iterations to solve.

Typical time-step selectors may use a limited collection of heuristic indicators to predict the subsequent step. While these have been effective for simple simulation models, as complexity increases, there is an increasing need for robust data-driven time-step selection algorithms. Dynamic and static workflows are described that use a diverse set of physical (e.g. well data) and mathematical (e.g. CFL) indicators to build a predictive ML model. These can be pre- or dynamically-trained to generate an optimal inference model. The trained model can also be reinforced as new data becomes available and efficiently used for transfer learning.

In some embodiment, the workflows described herein may follow three steps—training, inference and reinforcement. A first workflow may involve pre-training a ML model from a set of data generated by running a simulation model with a relaxed time-step strategy and then using the trained model as an inference engine within the simulator framework. The training data may be generated by the simulator ranges from direct physical quantities to derived mathematical properties of the system. The optimum time-step size may be generated for the training data comes from various sources. The optimum time-step size may allow the simulator to produce improved results when used.

One technique described in this disclosure is to request very big time-steps in the simulator during the training step. If a time-step is successful, it is taken as a training sample point. However, when a time-step fails and requires chopping, the (larger) failed time-step attempts are filtered out and the (smaller) successful attempts are added to the training set. This process may generate training data for each feature set with its corresponding optimum time-step size. The optimum time-step size may be one or more of those improved time-step sizes that have had successful attempts. The inference engine then produces optimum time-steps which can be applied to any simulation model that is similar in nature to the model that was used to generate the training data (and the “similarity” between models can be determined by fingerprinting the input data for each model). The ML model can also be reinforced (update the training data with time-step behavior from subsequent runs) to iteratively improve the accuracy of the time-step predictor.

An advantage of the present disclosure is it describes embodiments that can be used to speed up workflows whenever a reservoir engineer needs to run a reservoir simulator on many similar variants of a simulation model. The information gained from the simulation of the first model is used to generate an improved and robust time-step length predictor which allows all the other models to be run more efficiently. Target workflows include ensemble optimizations, history matching and prediction.

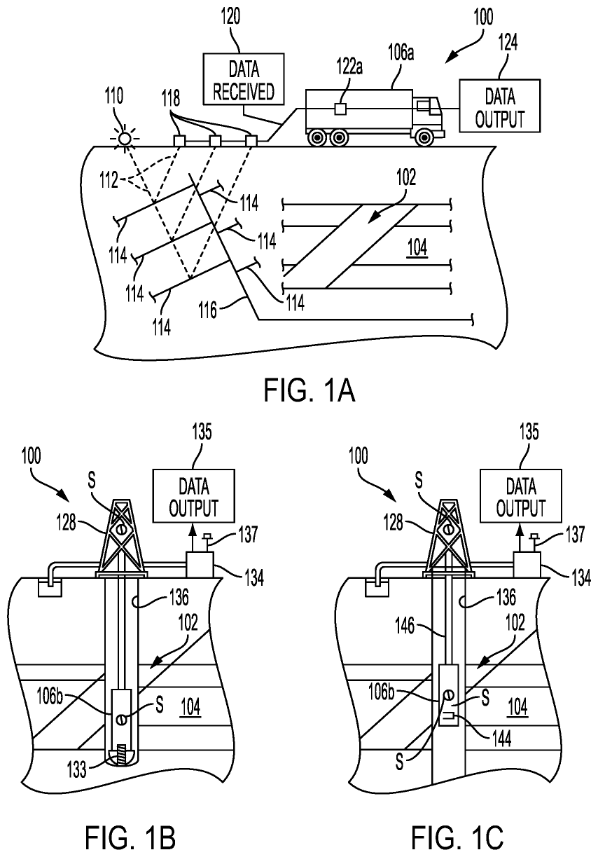

FIGS. 1A-1C illustrate simplified, schematic views of oilfield 100 having subterranean formation 102 containing reservoir 104 therein in accordance with implementations of various technologies and techniques described herein. FIG. 1A illustrates a survey operation being performed by a survey tool, such as seismic truck 106a, to measure properties of the subterranean formation. The survey operation is a seismic survey operation for producing sound vibrations. In FIG. 1A, one such sound vibration, e.g., sound vibration 112 generated by source 110, reflects off horizons 114 in earth formation 116. A set of sound vibrations is received by sensors, such as geophone-receivers 118, situated on the earth's surface. The data received 120 is provided as input data to a computer 122a of the seismic truck 106a, and responsive to the input data, computer 122a generates seismic data output 124. This seismic data output may be stored, transmitted or further processed as desired, for example, by data reduction.

FIG. 1B illustrates a drilling operation being performed by drilling tools 106b suspended by rig 128 and advanced into subterranean formations 102 to form wellbore 136. The drilling tools are advanced into subterranean formations 102 to reach reservoir 104. Each well may target one or more reservoirs. The drilling tools may be adapted for measuring downhole properties using logging while drilling tools. The logging while drilling tools may also be adapted for taking core sample 133 as shown.

The drilling tool 106b may include downhole sensor S adapted to perform logging while drilling (LWD) data collection. The sensor S may be any type of sensor.

Computer facilities may be positioned at various locations about the oilfield 100 (e.g., the surface unit 134) and/or at remote locations. Surface unit 134 may be used to communicate with the drilling tools and/or offsite operations, as well as with other surface or downhole sensors. Surface unit 134 is capable of communicating with the drilling tools to send commands to the drilling tools, and to receive data therefrom. Surface unit 134 may also collect data generated during the drilling operation and produce data output 135, which may then be stored or transmitted.

In some embodiments, sensors (S), such as gauges, may be positioned about oilfield 100 to collect data relating to various oilfield operations as described previously. As shown, sensor (S) is positioned in one or more locations in the drilling tools and/or at rig 128 to measure drilling parameters, such as weight on bit, torque on bit, pressures, temperatures, flow rates, compositions, rotary speed, and/or other parameters of the field operation. In some embodiments, sensors (S) may also be positioned in one or more locations in the wellbore 136.

Drilling tools 106b may include a bottom hole assembly (BHA) (not shown), generally referenced, near the drill bit (e.g., within several drill collar lengths from the drill bit). The bottom hole assembly includes capabilities for measuring, processing, and storing information, as well as communicating with surface unit 134. The bottom hole assembly further includes drill collars for performing various other measurement functions.

The bottom hole assembly may include a communication subassembly that communicates with surface unit 134. The communication subassembly is configured to send signals to and receive signals from the surface using a communications channel such as mud pulse telemetry, electro-magnetic telemetry, or wired drill pipe communications. The communication subassembly may include, for example, a transmitter that generates a signal, such as an acoustic or electromagnetic signal, which is representative of the measured drilling parameters. It will be appreciated by one of skill in the art that a variety of telemetry systems may be employed, such as wired drill pipe, electromagnetic or other known telemetry systems.

The data gathered by sensors (S) may be collected by surface unit 134 and/or other data collection sources for analysis or other processing. An example of the further processing is the generation of a grid for use in the computation of a juxtaposition diagram as discussed below. The data collected by sensors (S) may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis. The data may be stored in separate databases, or combined into a single database.

Surface unit 134 may include transceiver 137 to allow communications between surface unit 134 and various portions of the oilfield 100 or other locations. Surface unit 134 may also be provided with or functionally connected to one or more controllers (not shown) for actuating mechanisms at oilfield 100. Surface unit 134 may then send command signals to oilfield 100 in response to data received. Surface unit 134 may receive commands via transceiver 137 or may itself execute commands to the controller. A processor may be provided to analyze the data (locally or remotely), make the decisions and/or actuate the controller.

FIG. 1C illustrates a production operation being performed by production tool 106c deployed by rig 128 having a Christmas tree valve arrangement into completed wellbore 136 for drawing fluid from the downhole reservoirs into rig 128. The fluid flows from reservoir 104 through perforations in the casing (not shown) and into production tool 106c in wellbore 136 and to rig 128 via gathering network 146.

In some embodiments, sensors (S), such as gauges, may be positioned about oilfield 100 to collect data relating to various field operations as described previously. As shown, the sensors (S) may be positioned in production tool 106c or rig 128.

While FIGS. 1A-1C illustrate tools used to measure properties of an oilfield, it will be appreciated that various measurement tools capable of sensing parameters, such as seismic two-way travel time, density, resistivity, production rate, etc., of the subterranean formation and/or its geological formations may be used. As an example, wireline tools may be used to obtain measurement information related to casing attributes. The wireline tool may include a sonic or ultrasonic transducer to provide measurements on casing geometry. The casing geometry information may also be provided by finger caliper sensors that may be included on the wireline tool. Various sensors may be located at various positions along the wellbore and/or the monitoring tools to collect and/or monitor the desired data. Other sources of data may also be provided from offsite locations.

The field configurations of FIGS. 1A-1C are intended to provide a brief description of an example of a field usable with oilfield application frameworks. Part, or all, of oilfield 100 may be on land, water, and/or sea. Also, while a single field measured at a single location is depicted, oilfield applications may be utilized with any combination of one or more oilfields, one or more processing facilities and one or more wellsites. An example of processing of data collected by the sensors is the generation of a grid for use in the computation of a juxtaposition diagram as discussed below.

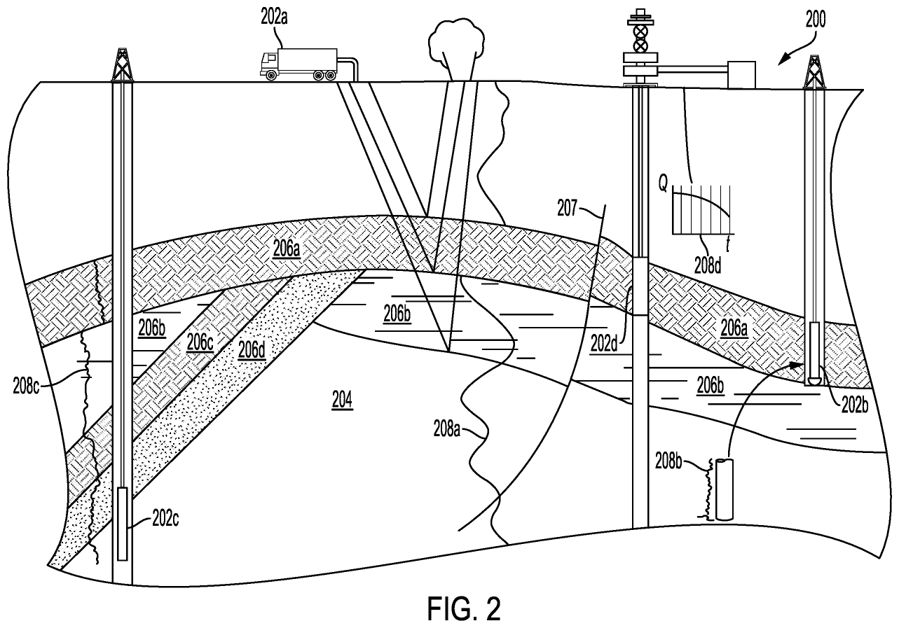

FIG. 2 illustrates a schematic view, partially in cross section of oilfield 200 having data acquisition tools 202a, 202b, 202c and 202d positioned at various locations along oilfield 200 for collecting data of subterranean formation 204 in accordance with implementations of various technologies and techniques described herein. Data acquisition tools 202a-202d may be the same as data acquisition tools 106a-106d of FIGS. 1A-1C, respectively, or others not depicted. As shown, data acquisition tools 202a-202d generate data plots or measurements 208a-208d, respectively. These data plots are depicted along oilfield 200 to demonstrate the data generated by the various operations.

Data plots 208a-208c are examples of static data plots that may be generated by data acquisition tools 202a-202c, respectively; however, it should be understood that data plots 208a-208c may also be data plots that are updated in real time. These measurements may be analyzed to better define the properties of the formation(s) and/or determine the accuracy of the measurements and/or for checking for errors. The plots of each of the respective measurements may be aligned and scaled for comparison and verification of the properties.

Static data plot 208a is a seismic two-way response over a period of time. Static plot 208b is core sample data measured from a core sample of the formation 204. The core sample may be used to provide data, such as a graph of the density, porosity, permeability, or some other physical property of the core sample over the length of the core. Tests for density and viscosity may be performed on the fluids in the core at varying pressures and temperatures. Static data plot 208c is a logging trace that provides a resistivity or other measurement of the formation at various depths.

A production decline curve or graph 208d is a dynamic data plot of the fluid flow rate over time. The production decline curve provides the production rate as a function of time. As the fluid flows through the wellbore, measurements are taken of fluid properties, such as flow rates, pressures, composition, etc.

Other data may also be collected, such as historical data, user inputs, economic information, and/or other measurement data and other parameters of interest. As described below, the static and dynamic measurements may be analyzed and used to generate models of the subterranean formation to determine characteristics thereof. Similar measurements may also be used to measure changes in formation aspects over time.

The subterranean structure 204 has a plurality of geological formations 206a-206d. As shown, this structure has several formations or layers, including a shale layer 206a, a carbonate layer 206b, a shale layer 206c and a sand layer 206d. A fault 207 extends through the shale layer 206a and the carbonate layer 206b. The static data acquisition tools are adapted to take measurements and detect characteristics of the formations.

While a specific subterranean formation with specific geological structures is depicted, it will be appreciated that oilfield 200 may contain a variety of geological structures and/or formations, sometimes having extreme complexity. In some locations, for example below the water line, fluid may occupy pore spaces of the formations. Each of the measurement devices may be used to measure properties of the formations and/or its geological features. While each acquisition tool is shown as being in specific locations in oilfield 200, it will be appreciated that one or more types of measurement may be taken at one or more locations across one or more fields or other locations for comparison and/or analysis.

The data collected from various sources, such as the data acquisition tools of FIG. 2, may then be processed and/or evaluated to form models reports for assessing a drill site.

In some embodiments, the model may include the a well's name, area and location (by latitude and longitude) (county and state) of the well, the well control number, rig contractor name and rig number, spud and rig release dates, weather and temperature, road condition and hole condition, and name of the person submitting the report.

In some embodiments, the model may include bits used (with size and serial numbers), depths (kelly bushing depth, ground elevation, drilling depth, drilling depth progress, water depth), drilling fluid losses and lost circulation, estimated costs (usually a separate document), fishing and side tracking, mud engineer's lithology of formations drilled and hydrocarbons observed, daily drilling issues, tubulars (casing and tubing joints and footages) run and cement used, vendors and their services, well bore survey results, work summary, work performed and planned.

In some embodiments, the model may include the hourly breakdown duration of single operations with codes that allow an instant view, understanding and summary of each phase, for example, rig up and rig down hours, drilling tangent (vertical), curve drilling (to change the direction of the drilling from vertical to horizontal) and lateral drilling (for horizontal wells), circulating the well, conditioning the mud, reaming the hole for safety to prevent stuck pipe, running casing, waiting on cement, nipple up and testing BOP's, trips in and out of the hole and surveys.

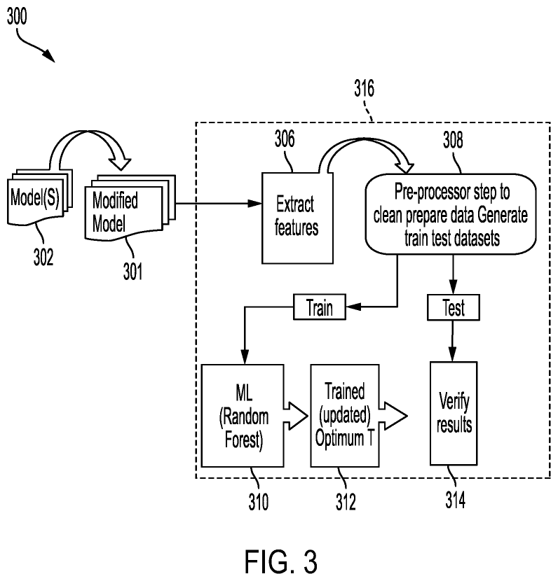

FIG. 3 shows a workflow 300 where a model is generated using the techniques described in FIGS. 1A-1C and FIG. 2, as shown in step 302. The model may be modified using an optimum time step strategy, as shown in step 304. The modified model may include features to train an ML model that are extracted from a simulation run of the modified model, as shown in stage 306. An ML pre-processor may update/clean the features and generate test/train models, as shown in stage 308. The processing steps involving optimizing time-steps are encapsulated by box 316.

In particular, the ML processor uses a training set for training an ML algorithm, as shown in stage 310. The ML algorithm may be of any type that utilizes the model of step 302. Moreover, a decision tree may be used to determine the optimum time-step using the training set, as shown in step 312. A test model may be used to test the model to verify results, as shown in step 314. Similar models can use optimized time-step by using the generated decision tree of step 312.

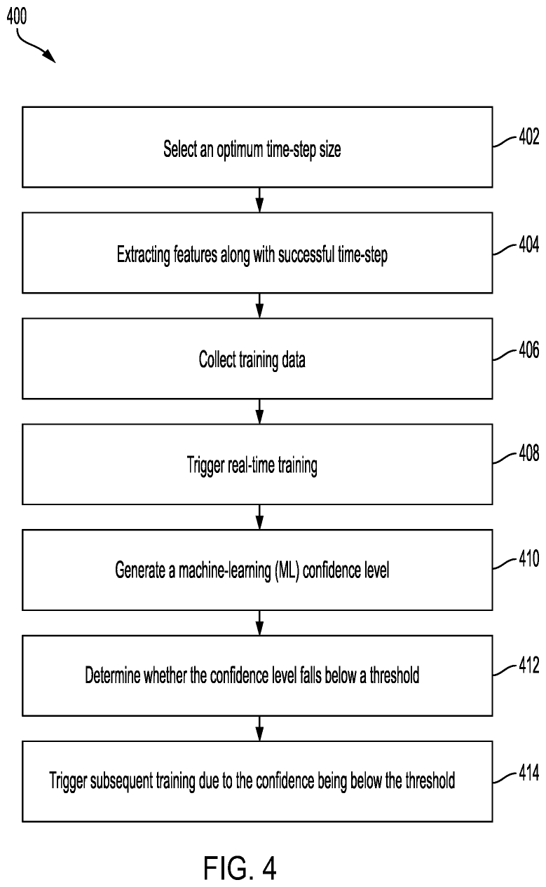

FIG. 4 shows a second workflow for a real-time train-infer-reinforce type model, in accordance with some embodiments. In this case, the simulation is started with selecting an optimum time-step size, as shown in step 402, which is determined by taking a big time-step and fine tuning the big time-step to get an improved or successful time-step sizes, and extracting features along with successful time-step sizes, as shown in step 404. The following information is collected to create training data, as shown in step 406. Once enough data is collected, a real-time, substantially instantaneous, training is triggered that generates an ML model, as shown in step 408. For the following steps, the ML model acts as the inference engine and generates optimum time-steps. An ML time-step confidence level is generated and continually updated and uses the success of the actual simulator time-step to compare the ML generated time-step with that generated by the simulator's existing heuristic algorithms, as shown in step 410.

This confidence level determines the current reliability of the ML time-steps at this stage of the simulation. If the confidence level falls below a threshold, the system triggers a process to generate more training data (using a period of attempted large time-steps) to append to the existing feature set, as shown in step 412. Subsequent training is also triggered, and the inference engine is updated, as shown in step 414. The mechanism for adjusting confidence level between ML and heuristic time-step selections, and selecting which approach to currently use, can itself be configured as a machine learning classifier. This setup takes the dynamic workflow into the Artificial Intelligence territory. One or multiple ML algorithms/models may then control one or multiple slave ML models thus driving the simulator forward.

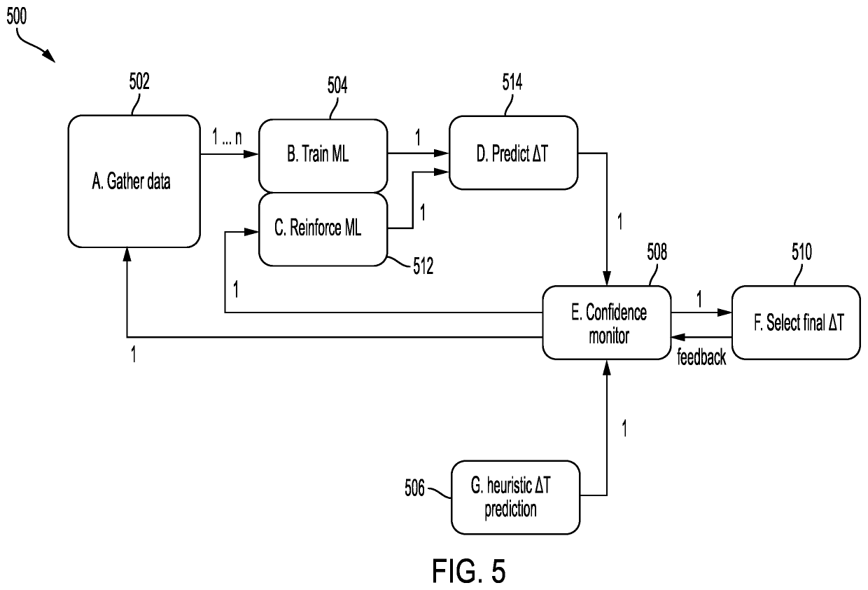

FIG. 5 shows a setup of a dynamic workflow 500, in accordance to some embodiments. The first process step, represented by step 502, may be triggered at the start of a simulation run. At this point an aggressive time-stepping strategy may be employed that can drive the simulator forward by taking it to the numerical limits of the given model. This can result in failed time-steps which will be discarded from the training data and the successful time-steps, which would also represent the optimal set of step-sizes, can be added to the training set. A static and a dynamic fingerprint of the model may be taken which would include the model properties, numerical setup and real-time or substantially instantaneous parameters such as number of wells opening and closing during the simulation. Once enough data is generated, step 504 will be triggered, which may train a ML model using a specified algorithm. This trained model may be used to predict time-steps for the simulator.

Concurrently, step 506 may produce a heuristic time-step from the existing methods in the simulator. The ML predicted and the heuristic time-steps may be compared within another ML classifier that will determine the confidence level. This may be carried out in step 508. A confidence monitor may select a time-step and feed it into the simulator. The simulator in turn executes and sends back the result of the nonlinear convergence behavior, as shown in step 510. The confidence monitor then analyzes this feedback and either takes a decision to reinforce the ML model at step 512 or decides to re-generate an entirely new set of optimum time-steps (from step 502) and re-train a new model (in step 504). The reinforcement step will not perturb the model or only slightly perturbs the model but adds a reliable time-step to increase the confidence level of the predictor at. These stages together result in an AI based time-step selection strategy rather than just an ML inference engine. The numbers on the arrows show the number of operations. At the time of generating new data points (steps 502-504), multiple time-steps are produced while at other stages one step at a time is dealt with.

In some embodiments, the static workflow 300 as well as the dynamic workflow 500 can be used in conjunction with one another. The static workflow 300 can give an initial model which is consumed by the dynamic model 500 at step 502 (in FIG. 5) and just reinforced as needed during the simulation.

The results for the ML-enhanced time-step selection strategy for reservoir simulation are now discussed. These results are obtained by the application of the first workflow 300 to a range of models representing different physical processes.

Table 1 shows an example set of features generated from the simulator. The training data includes only the successful time-steps (indicated as “Pass”). This ensures that the ML model is trained to an optimum time-step size. This training data can also be generated in real-time or substantially instantaneous.

TABLE 1
Example set of features used for ML-enhanced time-stepping

| | | | | Max | Max | | |
|---|---|---|---|---|---|---|---|
| Saturation | Thermodynamic | | Last | pressure | Saturation | | |
| CFL | CFL | Iterations | Timestep | Change | Change | Timestep | Reason |
| 5.29887 | 6.08408 | 38 | 3.17188 | 98.7152 | 0.169302 | 2.77539 | Fail |
| 1827.78 | 11.6235 | 11 | 9.71387 | 128.795 | 0.130077 | 9.71387 | Pass |
| 1906.08 | 11.7415 | 6 | 9.71387 | 80.5125 | 0.157663 | 15 | Pass |
| 1312.67 | 9.94951 | 5 | 8 | 45.3109 | 0.074218 | 8 | Pass |
| 1470.28 | 8.37504 | 4 | 8 | 41.8093 | 0.095476 | 15 | Pass |
| 1795.83 | 426.634 | 65 | 0.007812 | 58.8442 | 0.12229 | 0.062006 | Fail |

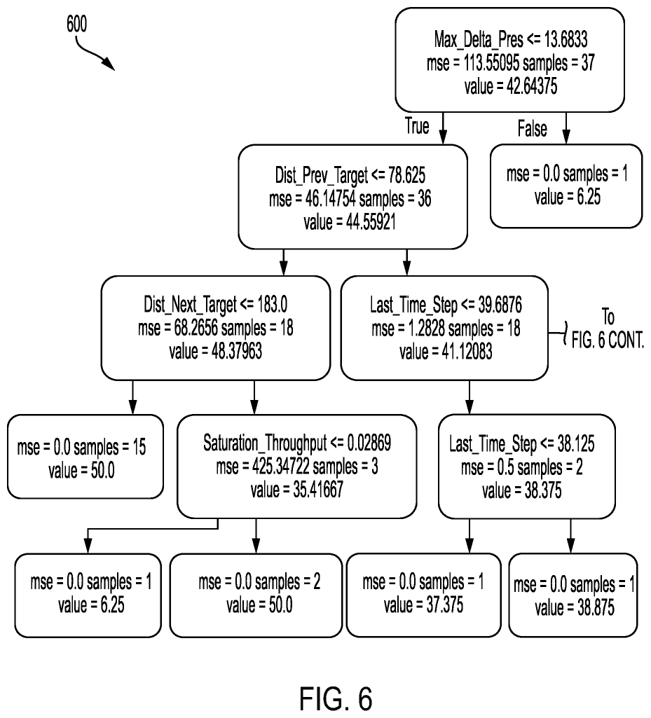

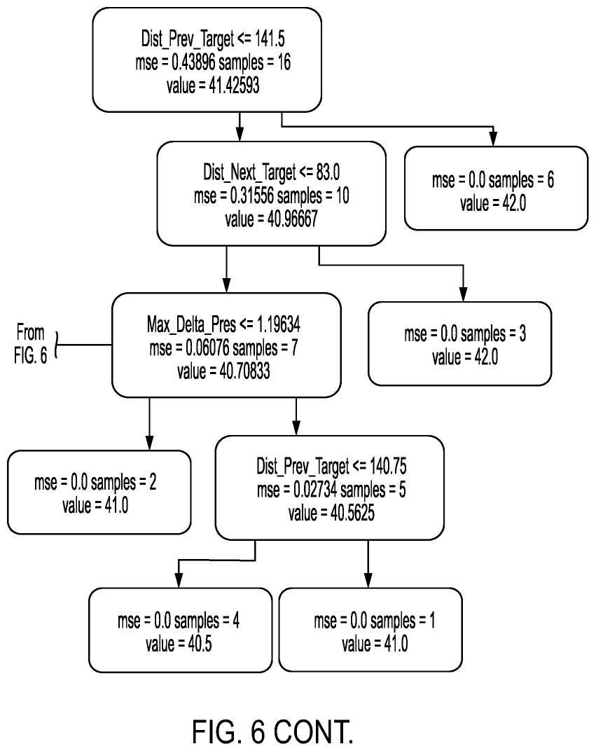

In this example the application is shown for a random forest regression. Similar results were also obtained for a neural network. FIG. 6 shows a snapshot of part of a tree 600 generated for an isothermal compositional model. In this tree 600, the pressure change results in the largest variance in the data and hence is the primary splitting data. The interaction between the various chemical species is governed by the thermodynamic state of the system and pressure change is the primary state variable that affects this. The generated tree agrees with expectations from logical deductions based on the physics of the system.

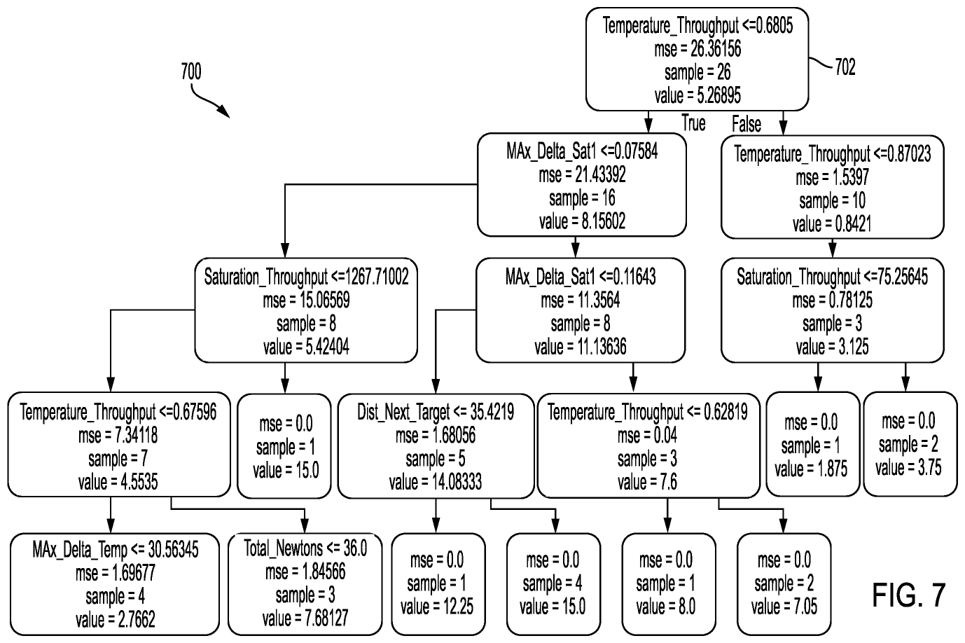

FIG. 7 depicts a snapshot of a tree 700 from a random forest model for a thermal simulation model, in accordance with some embodiments. In this case, the temperature CFL number becomes an important feature as the local changes in temperature introduce stiffness to the governing partial differential equation. The greater the stiffness of the equation, the more difficult it is to solve numerically. FIG. 7 shows part of the random forest tree 700 and the top node 702 is the temperature CFL number.

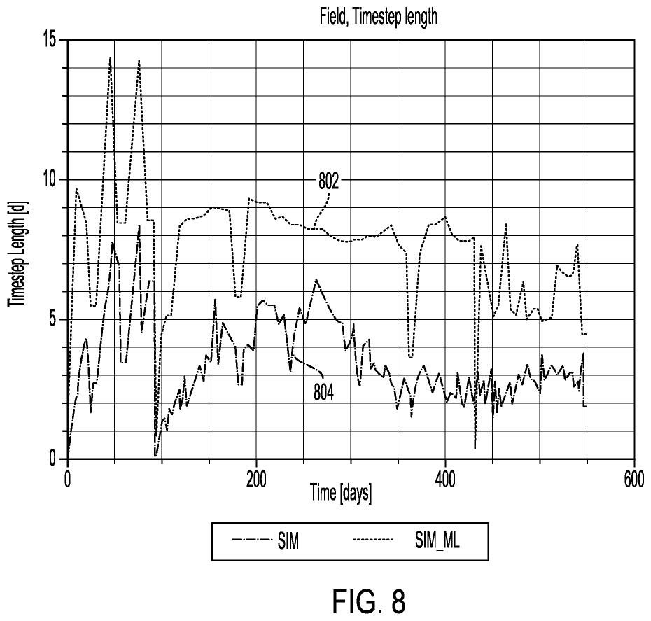

FIG. 8 depicts a time-step comparison for a thermal simulation model, in accordance with some embodiments. Curve 802 shows the time-step sizes for the ML-enhanced model while curve 804 is the default simulation run. The ML generated time-steps are more optimized than the default run. In some embodiments, the ML may be able to drive the simulator with twice the time-step sizes.

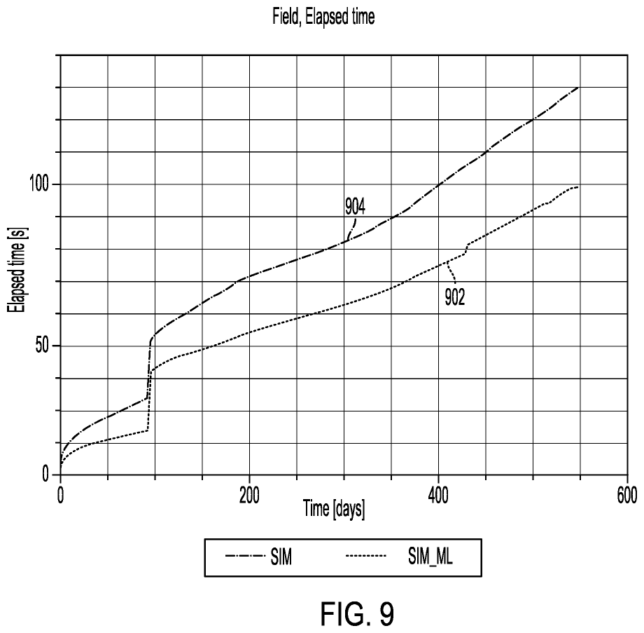

FIG. 9 shows the run time comparison for the same model in accordance with some embodiments. ML-enhanced run 902 resulted in about 25% reduction in the simulation run time 904. Similar results were obtained for other cases ranging in complexity and nonlinearity.

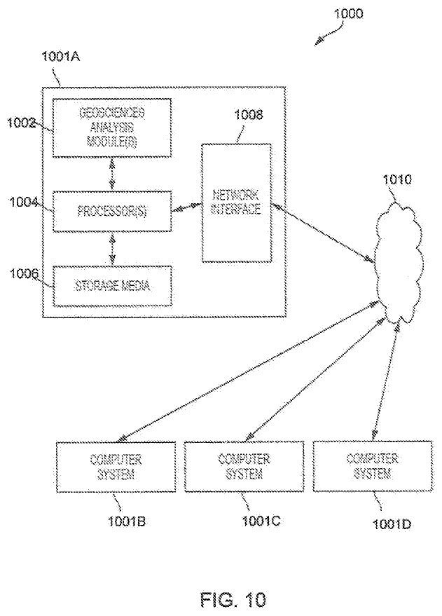

FIG. 10 depicts an example computing system 1000 in accordance with carrying out some of the methods of the present disclosure, in accordance with some embodiments. For example, the computing system 1000 may perform the workflows 300, 400, and 500 described herein.

The computing system 1000 can be an individual computer system 1001A or an arrangement of distributed computer systems. The computer system 1001A includes one or more geosciences analysis modules 1002 that are configured to perform various tasks according to some embodiments, such as one or more methods disclosed herein. To perform these various tasks, geosciences analysis module 1002 executes independently, or in coordination with, one or more processors 1004, which is (or are) connected to one or more storage media 1006. The processor(s) 1004 is (or are) also connected to a network interface 1008 to allow the computer system 1001A to communicate over a data network 1010 with one or more additional computer systems and/or computing systems, such as 1001B, 1001C, and/or 1001D (note that computer systems 1001B, 1001C and/or 1001D may or may not share the same architecture as computer system 1001A, and may be located in different physical locations, e.g., computer systems 1001A and 1001B may be on a ship underway on the ocean, while in communication with one or more computer systems such as 1001C and/or 1001D that are located in one or more data centers on shore, other ships, and/or located in varying countries on different continents). Note that data network 1010 may be a private network, it may use portions of public networks, it may include remote storage and/or applications processing capabilities (e.g., cloud computing).

A processor can include a microprocessor, microcontroller, processor module or subsystem, programmable integrated circuit, programmable gate array, or another control or computing device.

The storage media 1006 can be implemented as one or more computer-readable or machine-readable storage media. Note that while in the example embodiment of FIG. 10 storage media 1006 is depicted as within computer system 1001A, in some embodiments, storage media 1006 may be distributed within and/or across multiple internal and/or external enclosures of computing system 1001A and/or additional computing systems. Storage media 1006 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; optical media such as compact disks (CDs) or digital video disks (DVDs), BluRays or any other type of optical media; or other types of storage devices. “Non-transitory” computer readable medium refers to the medium itself (i.e., tangible, not a signal) and not data storage persistency (e.g., RAM vs. ROM).

Note that the instructions or methods discussed above can be provided on one computer-readable or machine-readable storage medium, or alternatively, can be provided on multiple computer-readable or machine-readable storage media distributed in a large system having possibly plural nodes and/or non-transitory storage means. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions or located at a remote site from which machine-readable instructions can be downloaded over a network for execution.

It should be appreciated that computer system 1001A is one example of a computing system, and that computer system 1001A may have more or fewer components than shown, may combine additional components not depicted in the example embodiment of FIG. 10, and/or computer system 1001A may have a different configuration or arrangement of the components depicted in FIG. 10. The various components shown in FIG. 10 may be implemented in hardware, software, or a combination of both, hardware and software, including one or more signal processing and/or application specific integrated circuits.

It should also be appreciated that while no user input/output peripherals are illustrated with respect to computer systems 1001A, 1001B, 1001C, and 1001D, many embodiments of computing system 1000 include computing systems with keyboards, touch screens, displays, etc. Some computing systems in use in computing system 1100 may be desktop workstations, laptops, tablet computers, smartphones, server computers, etc.

Further, the steps in the processing methods described herein may be implemented by running one or more functional modules in an information processing apparatus such as general-purpose processors or application specific chips, such as ASICs, FPGAs, PLDs, or other appropriate devices. These modules, combinations of these modules, and/or their combination with general hardware are included within the scope of protection of the disclosure.

In some embodiments, a computing system is provided that comprises at least one processor, at least one memory, and one or more programs stored in the at least one memory, wherein the programs comprise instructions, which when executed by the at least one processor, are configured to perform any method disclosed herein.

In some embodiments, a computer readable storage medium is provided, which has stored therein one or more programs, the one or more programs comprising instructions, which when executed by a processor, cause the processor to perform any method disclosed herein.

In some embodiments, a computing system is provided that comprises at least one processor, at least one memory, and one or more programs stored in the at least one memory; and means for performing any method disclosed herein.

In some embodiments, an information processing apparatus for use in a computing system is provided, and that includes means for performing any method disclosed herein.

In some embodiments, a graphics processing unit is provided, and that includes means for performing any method disclosed herein.

Simulators as discussed herein are used to run field development planning cases in the oil and gas industry. These involve running of thousands of such cases with slight variations in the model setup. Embodiments of the subject disclosure can be applied readily to such applications and the resulting gains are significant. In optimization scenarios, the learning can be transferred readily, and this would avoid the need to re-train several models. In cases where the models show large variations in the physical or mathematical properties, reinforcement learning will be triggered which will adapt the ML model to the new feature ranges. Similarly, the dynamic framework can also be applied to standalone models and coupled with the static workflow.

Furthermore, there are potential applications outside the oil and gas industry such as computational fluid dynamics (CFD) studies, ground water flows, weather prediction, magneto-hydrodynamics (MHD), etc. With many applications moving to the cloud, this also provides a framework to optimize the simulation cloud workflows and solutions.

The subject matter of the disclosure addresses the issue of inefficient (sub-optimal) choice of time-step length in a reservoir simulator which leads to wasted computational effort and longer simulation times (correlates directly with cost in cloud computing). This means that reservoir engineers take longer to make operational decisions. Steps that are too large need to be reduced and repeated—a process called chopping; when steps are too small, more steps are required during the simulation which increases the number of computations.

Typical time-step choice approaches used in reservoir simulators look at basic parameters from the previous time-step to decide if it should be increased or decreased, but do not consider many of the physical measures of complexity available in the simulator.

Embodiments described herein incorporate those measures into a practical workflow to predict time-steps which are as large as possible and can be solved without the need to chop.

In static mode, information gained in a single simulation run (which only needs to be long enough to capture the main behaviors of the model) with relaxed time-stepping restrictions can be used to train a robust intelligent time-step selection for use in subsequent runs of similar models. Alongside many of the normal simulation numerical parameters, the information used includes easily available simulation “physical” information (such as CFL number) which means it is much more suited for use in a wider range of simulation models.

In a dynamic mode, the system compares the time-step size that would have been selected by the trained ML model and the simulator's underlying heuristic algorithms to compute a confidence that the ML time-step is reliable. This confidence level can be adjusted based on the performance of the actual time-step used in order to determine when the model should be used and when its training needs to be updated.

The embodiments described herein can be used to speed up workflows whenever a reservoir engineer needs to run a reservoir simulator on many similar variants of a simulation model. The information gained from the simulation of the first model is used to generate an improved and robust time-step length predictor which allows the other models to be run more efficiently. Target workflows include ensemble optimizations, history matching and prediction.

Existing methods can be divided into two sub-classes—physical and mathematical. Physical methods are based on specific parameters such as the magnitude of changes in the state variables, type of physics, etc. while the mathematical methods are based on concepts such as error estimates, convergence theorems, number of iterations, etc. Specialist knowledge may be used to tune these methods in order to extract optimal performance.

This disclosure describes a machine learning workflow that learns from both the physical state and the mathematical parameters of the system. This results in an optimal performance and prevents a need for any tuning in order to achieve this. Another advantage is that there is no need to run multiple simulations to produce training data sets, rather a real time learning model is described.

The embodiments described herein can be used on the cloud without the need to share data or models. It uses physical information and ML and utilizes less simulations.

The embodiments described herein can be used within simulators to achieve efficient models and improve run times.

In some embodiments, a workflow may be used to generate optimized time-steps for general numerical simulation. This results in a reduction in simulation time and leads to more efficient field development planning for oil and gas extraction. In some embodiments, a controllable parameter may be trained against a set of diagnostic numerical and physical features within the simulator and the controllable parameter is optimized. There is no need for post-processing of existing simulation results as this is real-time time-step prediction during a simulation. In some embodiments, an AI based dynamic time-step selection strategy is described. ML time-steps are dynamically compared against simulator heuristic time-steps to continually update a confidence level which indicates when the ML time-steps are reliable and when the ML system needs more training.

The embodiments described herein can be used for stand-alone simulations or closed loop optimization routines and can be implemented as an on-premise standalone solution as well as a cloud solution.

While various embodiments in accordance with the disclosed principles have been described above, it should be understood that they have been presented by way of example only and are not limiting.

Furthermore, the above advantages and features are provided in described embodiments, but shall not limit the application of such issued claims to processes and structures accomplishing any or all of the above advantages.

1. A method for modeling a reservoir comprising:
receiving, using one or more computing device processors, a reservoir model associated with a reservoir workflow process;
modifying, using the one or more computing device processors, the reservoir model associated with the reservoir workflow process using an optimum time-step strategy;
extracting, using the one or more computing device processors, features from the reservoir model along with first time-step sizes;
generating, using the one or more computing device processors, a first set of data for devising a training set using the first time-step sizes;
collecting, using the one or more computing device processors, a selected amount of the first set of data for the training set;
determining, using the one or more computing device processors, whether the selected amount of the first set of data reaches a predetermined level;
in response to the selected amount of the first set of data reaching the predetermined level, triggering a real-time training using the training set and a machine learning (ML) algorithm;
generating, using the one or more computing device processors, an ML model having second time-step sizes using the training set;
comparing, using the one or more computing device processors, the first time-step sizes and the second time-step sizes to generate a confidence level;
selecting, using the one or more computing device processors, the first step-sizes or the second step-sizes based on the confidence level;
sending, using the one or more computing device processors, the selected step-sizes to a simulator for processing;
receiving, using the one or more computing device processors, results from the simulator that used the selected step-sizes; and
determining, using the one or more computing device processors, whether results from the simulator require updating the training set.

2. The method of claim 1, wherein receiving the reservoir model for the reservoir workflow process comprises information for creating a reservoir model.

3. The method of claim 1, wherein modifying the reservoir model associated with the reservoir workflow process comprises inputting time-step information.

4. The method of claim 1, wherein extracting features from the reservoir model comprises receiving the first time-step sizes from one or more heuristic options.

5. The method of claim 1, wherein generating the first set of data comprises running a simulation model with a relaxed time-step strategy.

6. The method of claim 1, wherein generating the first set of data comprises accessing direct physical quantities to derived mathematical properties of the reservoir.

7. The method of claim 1, wherein generating the first set of data comprises determining whether each of the first time-step sizes meets a criteria for optimal first time-step sizes.

8. The method of claim 7, wherein generating the first set of data comprises devising the training set using the optimal first time-step sizes.

9. The method of claim 7, wherein generating the first set of data comprises removing the first time-step sizes that do not meet the criteria.

10. A method for modeling complex processes comprising:
receiving, using one or more computing device processors, a model associated with a workflow process;
modifying, using the one or more computing device processors, the model associated with workflow process using an optimum time-step strategy;
extracting, using the one or more computing device processors, features from the model along with first time-step sizes used for analysis;
generating, using the one or more computing device processors, a first set of data for devising a training set using the first time-step sizes;
collecting, using the one or more computing device processors, a selected amount of the first set of data for the training set;
determining, using the one or more computing device processors, whether the selected amount of the first set of data reaches a predetermined level;
in response to the selected amount of the first set of data reaching the predetermined level, triggering a real-time training of a machine learning (ML) algorithm using the training set;
generating, using the one or more computing device processors, an ML model having second time-step sizes using the training set;
comparing, using the one or more computing device processors, the first time-step sizes and the second time-step sizes to generate a confidence level;
determining whether the confidence level is below a threshold; and
in response to the confidence level being below the threshold, updating, using the one or more computing device processors, the training set.

11. The method of claim 10, wherein generating the ML model comprises generating the second step-sizes using the ML model.

12. The method of claim 10, wherein updating the training set comprises generating a second set of data.

13. The method of claim 12, wherein updating the training set comprises generating a second training set by appending the training set and the second set of data.

14. A system for modeling a reservoir, the system comprising
one or more computing device processors; and
one or more computing device memories, coupled to the one or more computing device processors, the one or more computing device memories storing instructions executed by the one or more computing device processors, wherein the instructions are configured to:
receive a reservoir model associated with a reservoir workflow process;
modify the reservoir model associated with reservoir workflow process using an optimum time-step strategy;
extract features from the reservoir model along with first time-step sizes used for analysis;
generate a first set of data for devising a training set using the first time-step sizes;
collect a selected amount of the first set of data for the training set;
determine whether the selected amount of the first set of data reaches a predetermined level;
in response to the selected amount of the first set of data reaching the predetermined level, trigger a real-time training using the training set using a machine learning (ML) algorithm;
generate an ML model having second time-step sizes using the training set;
compare the first time-step sizes and the second time-step sizes to generate a confidence level;
select the first step-sizes or the second step-sizes base on the confidence level;
send the selected step-sizes to a simulator for processing;
receive results from the simulator that used the selected step-sizes; and
determine whether results from the simulator require updating the training set.

15. The system of claim 14, wherein the reservoir model comprises information for creating a reservoir model.

16. The system of claim 14, wherein the modified reservoir model comprises inputted time-step information.

17. The system of claim 14, wherein the first time-step sizes are from one or more heuristic options.

18. The system of claim 14, wherein the first set of data comprises direct physical quantities associated with the reservoir.

19. The method of claim 14, wherein each of the first time-step sizes meets a criteria for optimal first time-step sizes.

20. The method of claim 19, wherein the training set comprises data formed using the optimal first time-step sizes.
